(19) United States
(12) Patent Application Publication
(10) Pub. No.: US 2024/0038913 A1
(43) Pub. Date: Feb. 1, 2024

(54) LIGHT RECEIVING ELEMENT, DISTANCE MEASURING SYSTEM, AND ELECTRONIC DEVICE

(71) Applicant: SONY SEMICONDUCTOR SOLUTIONS CORPORATION, Kanagawa (JP)

(72) Inventors: Katsuhisa TANAKA, Kanagawa (JP); Yusuke OTAKE, Kanagawa (JP)

(73) Assignee: SONY SEMICONDUCTOR SOLUTIONS CORPORATION, Kanagawa (JP)

(21) Appl. No.: 18/253,172

(22) PCT Filed: Nov. 10, 2021
(86) PCT No.: PCT/JP2021/041270

§ 371 Date: May 16, 2023

(30) Foreign Application Priority Data
Nov. 24, 2020 (JP) 2020-194034

(51) Int. Cl. H01L 31/0352; H01L 31/107; H01L 27/146

(52) U.S. Cl. CPC H01L 31/035281; H01L 31/107; H01L 27/14607; G01S 7/4816

(57) ABSTRACT

The present technology relates to a light receiving element, a distance measuring system, and an electronic device capable of reducing unintended edge breakdown in a case where a pixel is miniaturized. A light receiving element includes a pixel that includes a PN junction region in which a first semiconductor region of a first conductivity type and a second semiconductor region of a second conductivity type opposite to the first conductivity type are joined, and a third semiconductor region of the first conductivity type that is not connected to any wiring outside the first semiconductor region near a first surface of a substrate on which a wiring that supplies a predetermined power supply voltage to the first semiconductor region is formed. The present technology can be applied to, for example, a distance measuring sensor that receives reflected light and measures a distance, and the like.

### TECHNICAL FIELD

The present technology relates to a light receiving element, a distance measuring system, and an electronic device, and more particularly relates to a light receiving element, a distance measuring system, and an electronic device configured to reduce unintended edge breakdown in a case where a pixel is miniaturized.

### BACKGROUND ART

In recent years, a distance measuring sensor that measures a distance by a Time-of-Flight (ToF) method has attracted attention. Examples of the distance measuring sensor include a distance measuring sensor using a single photon avalanche diode (SPAD) as a light receiving pixel. In the SPAD, avalanche amplification occurs when one photon enters a PN junction region of a high electric field in a state where a voltage (hereinafter referred to as ExcessBias) larger than a breakdown voltage is applied. By detecting the timing at which the current instantaneously flows at that time, the distance can be measured with high accuracy.

In Patent Document 1, the present applicant proposes a pixel structure including an avalanche photodiode connected to a cathode electrode, a separation region separating adjacent pixels, and a hole accumulation region accumulating holes on a side wall of the separation region, in which the hole accumulation region is electrically connected to an anode electrode.

### CITATION LIST

### Patent Document

Patent Document 1: WO 2018/074530

### SUMMARY OF THE INVENTION

### Problems to be Solved by the Invention

However, when the distance between the cathode electrode and the anode electrode is narrowed due to miniaturization of the pixel, unintended edge breakdown may occur.

The present technology has been made in view of such a situation, and is intended to reduce unintended edge breakdown in a case where a pixel is miniaturized.

### Solutions to Problems

A light receiving element according to a first aspect of the present technology includes a light receiving element that includes a pixel that includes a PN junction region in which a first semiconductor region of a first conductivity type and a second semiconductor region of a second conductivity type opposite to the first conductivity type are joined, and a third semiconductor region of the first conductivity type that is not connected to any wiring outside the first semiconductor region near a first surface of a substrate on which a wiring that supplies a predetermined power supply voltage to the first semiconductor region is formed.

A distance measuring system according to a second aspect of the present technology includes a light emitting section that emits irradiation light, and a light receiving element that receives reflected light of the irradiation light reflected by a subject, in which the light receiving element includes a pixel that includes a PN junction region in which a first semiconductor region of a first conductivity type and a second semiconductor region of a second conductivity type opposite to the first conductivity type are joined, and a third semiconductor region of the first conductivity type that is not connected to any wiring outside the first semiconductor region near a first surface of a substrate on which a wiring that supplies a predetermined power supply voltage to the first semiconductor region is formed.

An electronic device according to a third aspect of the present technology includes a light receiving element that includes a pixel that includes a PN junction region in which a first semiconductor region of a first conductivity type and a second semiconductor region of a second conductivity type opposite to the first conductivity type are joined, and a third semiconductor region of the first conductivity type that is not connected to any wiring outside the first semiconductor region near a first surface of a substrate on which a wiring that supplies a predetermined power supply voltage to the first semiconductor region is formed.

In the first to third aspects of the present technology, in a pixel in a light receiving element, there are provided a PN junction region in which a first semiconductor region of a first conductivity type and a second semiconductor region of a second conductivity type opposite to the first conductivity type are joined, and a third semiconductor region of the first conductivity type that is not connected to any wiring outside the first semiconductor region near a first surface of a substrate on which a wiring that supplies a predetermined power supply voltage to the first semiconductor region is formed.

The light receiving element, the distance measuring system, and the electronic device may be independent devices, or may be modules incorporated in other devices.

### BRIEF DESCRIPTION OF DRAWINGS

FIG. 1 is a diagram depicting a circuit configuration example of a pixel using a SPAD.

FIG. 2 is a graph describing an operation of the pixel in FIG. 1.

FIG. 3 is a diagram depicting a first configuration example of the pixel.

FIG. 4 is a diagram depicting a second configuration example of the pixel.

FIG. 5 is a diagram depicting a third configuration example of the pixel.

FIG. 6 is a diagram depicting a fourth configuration example of the pixel.

FIG. 7 is a diagram depicting a fifth configuration example of the pixel.

FIG. 8 is a diagram depicting a sixth configuration example of the pixel.

FIG. 9 is a diagram depicting a seventh configuration example of the pixel.

FIG. 10 is a diagram depicting the seventh configuration example of the pixel.

FIG. 11 is a diagram depicting an eighth configuration example of the pixel.

FIG. 12 is a diagram depicting the eighth configuration example of the pixel.

FIG. 13 is a diagram depicting a ninth configuration example of the pixel.

FIG. 14 is a diagram depicting the ninth configuration example of the pixel.

FIG. 15 is a diagram depicting a tenth configuration example of the pixel.

FIG. 16 is a block diagram depicting a configuration example of a distance measuring system to which the present technology is applied.

FIG. 17 is a block diagram depicting a first configuration example of a distance measuring sensor in FIG. 16.

FIG. 18 is a block diagram depicting a second configuration example of the distance measuring sensor in FIG. 16.

FIG. 19 is a block diagram depicting a configuration example of a smartphone serving as an electronic device to which the present technology is applied.

FIG. 20 is a block diagram depicting an example of a schematic configuration of a vehicle control system.

FIG. 21 is a diagram of assistance in explaining an example of installation positions of an outside-vehicle information detecting section and an imaging section.

### MODE FOR CARRYING OUT THE INVENTION

Hereinafter, embodiments for implementing the present technology (hereinafter referred to as embodiments) will be described. The description will be made in the following order.
1. Pixel circuit using SPAD
2. First Configuration Example of Pixel
3. Second Configuration Example of Pixel
4. Third Configuration Example of Pixel
5. Fourth Configuration Example of Pixel
6. Fifth Configuration Example of Pixel
7. Sixth Configuration Example of Pixel
8. Seventh Configuration Example of Pixel
9. Eighth Configuration Example of Pixel
10. Ninth Configuration Example of Pixel
11. Tenth Configuration Example of Pixel
12. Configuration Example of Distance Measuring System
13. Configuration Example for Electronic Device
14. Application Example to Mobile Body

Note that in the drawings referred to in the following description, the same or similar parts are denoted by the same or similar reference numerals. However, the drawings are schematic, and the relationship between the thickness and the plane dimension, the ratio of the thickness of each layer, and the like are different from the actual ones. Furthermore, the drawings may include portions having different dimensional relationships and ratios.

Furthermore, definitions of directions such as up and down in the following description are merely definitions for convenience of description, and do not limit the technical idea of the present disclosure. For example, when an object is observed by rotating the object by 90°, the upper and lower sides are read by converting into left and right, and when an object is observed by rotating the object by 180°, the upper and lower sides are read by inverting.

<1. Pixel Circuit Using SPAD>

The present technology can be applied to, for example, an avalanche photodiode (APD) applicable to a light receiving element such as a distance measuring sensor that measures a distance by a time-of-flight (ToF) method. An avalanche photodiode (APD) includes a Geiger mode in which it is operated at a bias voltage (hereinafter referred to as ExcessBias) higher than the breakdown voltage and a linear mode in which it is operated at a slightly high bias voltage near the breakdown voltage. The avalanche photodiode in the Geiger mode is also referred to as a single photon avalanche diode (SPAD). The SPAD can instantaneously detect one photon by multiplying carriers generated by photoelectric conversion in a PN junction region (multiplication region) of a high electric field.

Hereinafter, a case where the present technology is applied to a SPAD will be described as an example.

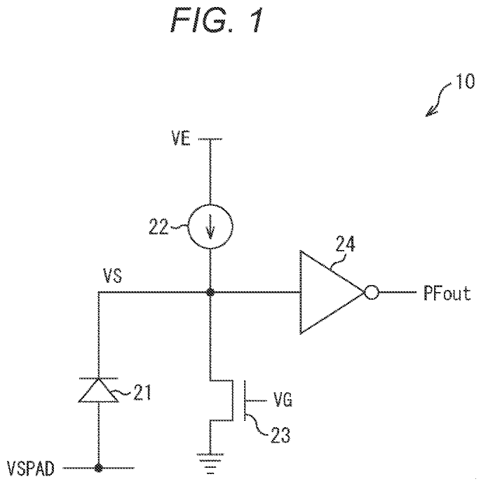

FIG. 1 illustrates a pixel circuit using a SPAD.

The pixel 10 in FIG. 1 includes a SPAD 21, a constant current source 22, a transistor 23, and an inverter 24.

A cathode of the SPAD 21 is connected to the constant current source 22, and is connected to an input terminal of the inverter 24 and a drain of the transistor 23. An anode of the SPAD 21 is connected to a power supply voltage VSPAD.

The SPAD 21 is a photodiode (single photon avalanche photodiode) that performs avalanche amplification of generated electrons and outputs a signal of a cathode voltage VS when incident light is incident. The power supply voltage VSPAD supplied to the anode of the SPAD 21 is, for example, a negative bias (negative potential) having the same voltage as a breakdown voltage VBD of the SPAD 21.

The constant current source 22 includes, for example, a P-type MOS transistor that operates in a saturation region, and performs passive quenching by acting as a quenching resistor. A power supply voltage VE (VE>0) is supplied to the constant current source 22. Note that, a pull-up resistor and the like may also be used for the constant current source 22 in place of the P-type MOS transistor.

In order to detect light (photon) with sufficient efficiency, an excessive bias larger than the breakdown voltage VBD of the SPAD 21 is applied to the SPAD 21.

The drain of the transistor 23 is connected to the cathode of the SPAD 21, the input terminal of the inverter 24, and the constant current source 22, and a source of the transistor 23 is connected to the ground (GND). A gating control signal VG is supplied to a gate of the transistor 23 from a pixel control circuit that drives a pixel.

In a case where the pixel 10 is an active pixel, a low (Lo) gating control signal VG is supplied from the pixel control circuit to the gate of the transistor 23. On the other hand, in a case where the pixel 10 is an inactive pixel, a high (Hi) gating control signal VG is supplied from the pixel control circuit to the gate of the transistor 23.

The inverter 24 outputs a Hi PFout signal when the cathode voltage VS as an input signal is Lo, and outputs a Lo PFout signal when the cathode voltage VS is Hi.

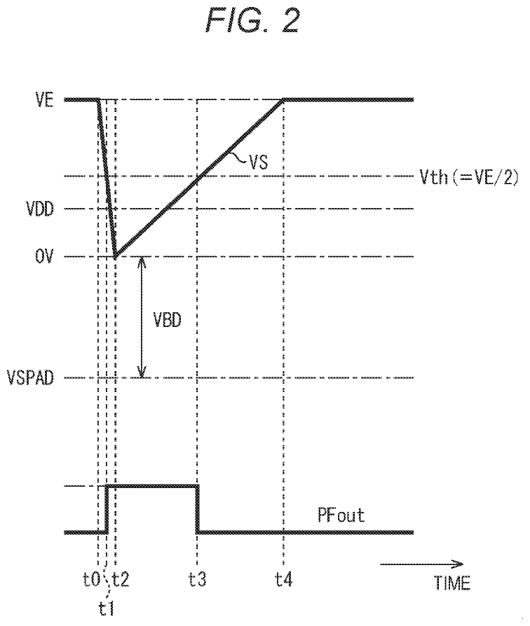

Next, an operation in a case where the pixel 10 is the active pixel will be described with reference to FIG. 2. FIG. 2 is a graph depicting a change in the cathode voltage VS of the SPAD 21 in response to incidence of a photon and a detection signal PFout.

First, in a case where the pixel 10 is the active pixel, the transistor 23 is set to off by the Lo gating control signal VG.

At a time before time t0 in FIG. 2, since the power supply voltage VE is supplied to the cathode of the SPAD 21 and the power supply voltage VSPAD is supplied to the anode, a reverse voltage larger than the breakdown voltage VBD is applied to the SPAD 21, thereby setting the SPAD 21 to the Geiger mode. In this state, the cathode voltage VS of the SPAD 21 is the same as the power supply voltage VE.

When the photon is incident on the SPAD 21 set in Geiger mode, avalanche multiplication occurs, and a current flows through the SPAD 21.

When avalanche multiplication occurs at time to and a current flows through the SPAD 21, after time t0, by the current flowing through the SPAD 21, a current also flows through the P-type MOS transistor as the constant current source 22, and a voltage drop occurs due to a resistance component of the MOS transistor.

When the cathode voltage VS of the SPAD 21 becomes lower than 0 V at time t2, the voltage becomes lower than the breakdown voltage VBD, so that the avalanche amplification is stopped. Here, an operation in which the current generated by the avalanche amplification flows through the constant current source 22 to generate the voltage drop, and the cathode voltage VS becomes lower than the breakdown voltage VBD along with the generated voltage drop, thereby stopping the avalanche amplification is the quenching operation.

When the avalanche amplification is stopped, the current flowing through the constant current source 22 (P-type MOS transistor) gradually decreases, and at time t4, the cathode voltage VS returns to the original power supply voltage VE again, making it capable of detecting a next new photon (recharging operation).

The inverter 24 outputs the low (Lo) PFout signal when the cathode voltage VS, which is an input voltage, is equal to or higher than a predetermined threshold voltage Vth (=VE/2), and outputs the Hi PFout signal when the cathode voltage VS is lower than the predetermined threshold voltage Vth. In the example of FIG. 2, a high (Hi) PFout signal is output in a period from time t1 to time t3.

Note that, in a case where the pixel 10 is an inactive pixel, the Hi gating control signal VG is supplied from the pixel control circuit to the gate of the transistor 23, and the transistor 23 is turned on. Thus, the cathode voltage VS of the SPAD 21 becomes 0 V (GND), and the anode-cathode voltage of the SPAD 21 becomes equal to or lower than the breakdown voltage VBD, so that no reaction occurs even if the photon enter the SPAD 21.

<2. First Configuration Example of Pixel>

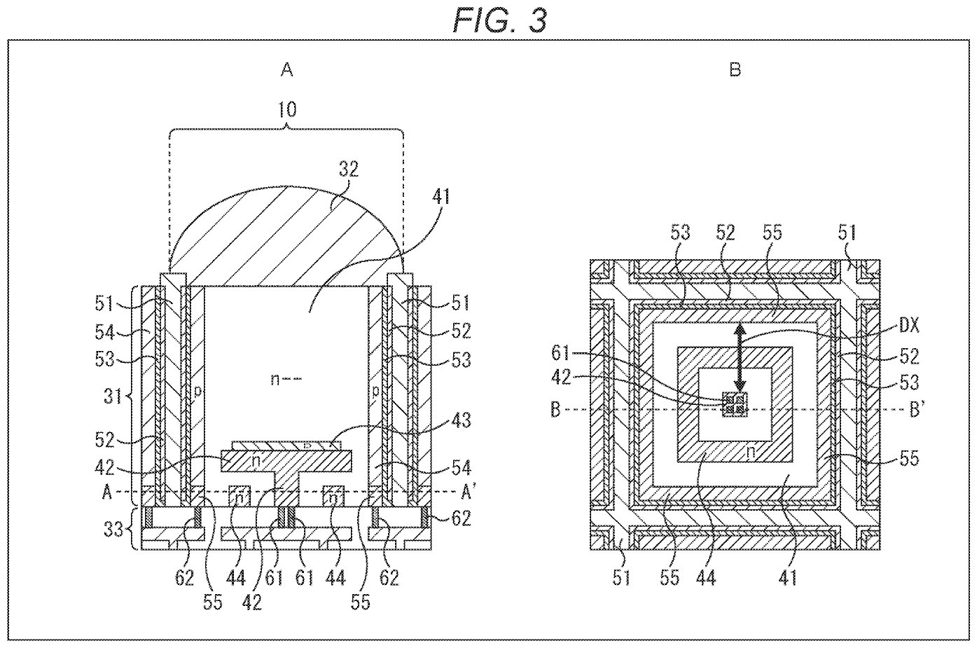

FIG. 3 is a diagram depicting a first configuration example of the pixel 10 using the SPAD 21 described above.

A of FIG. 3 is a cross-sectional view of the pixel 10 according to the first configuration example, and B of FIG. 3 is a plan view of the pixel 10 according to the first configuration example. The cross-sectional view of A of FIG. 3 illustrates a cross-sectional view taken along line B-B′ of B of FIG. 3, and the plan view of B of FIG. 3 illustrates a plan view taken along line A-A′ of A of FIG. 3.

As depicted in A of FIG. 3, the pixel 10 according to the first configuration example includes an on-chip lens 32 on one surface of the semiconductor substrate 31 formed by silicon or the like, and a wiring layer 33 on the other surface, in which wiring for supplying the power supply voltage VE to the cathode of the SPAD 21 or supplying the power supply voltage VSPAD to the anode is formed. In A of FIG. 3, the surface on which the wiring layer 33 is formed, which is a lower side of the semiconductor substrate 31, is a front surface side of the semiconductor substrate 31, and the surface on which the on-chip lens 32 is formed is a back surface side. An incident surface on which reflected light reflected from an object is incident is the back surface side on which the on-chip lens 32 is formed. Therefore, the pixel 10 has a back-illuminated pixel structure that receives incident light on the back surface side of the semiconductor substrate 31.

As depicted in A of FIG. 3, the pixel 10 includes an n-well 41 below the on-chip lens 32 in the semiconductor substrate 31, and a high-concentration n-type semiconductor region 42, a high-concentration p-type semiconductor region 43, and a high-concentration n-type semiconductor region 44 are formed in the n-well 41.

The n-well 41 is formed by being controlled to n-type (n−−) in which impurity concentration of the semiconductor substrate 31 is thin, and forms an electric field that transfers electrons generated by photoelectric conversion in the pixel 10 to an avalanche multiplication region. Note that instead of the n-well 41, a p-well in which the impurity concentration of the semiconductor substrate 31 is controlled to p-type may be formed.

The high-concentration n-type semiconductor region 42 is a thick n-type (first conductivity type) semiconductor region (first semiconductor region) formed in a predetermined plane region at a predetermined depth from the front surface side of the semiconductor substrate 31, has a substantially T-shaped cross-sectional shape extending in a longitudinal direction (depth direction) at a central portion of the pixel region, and is formed up to the front surface of the semiconductor substrate 31. Then, at an interface on the front surface side of the semiconductor substrate 31, the high-concentration n-type semiconductor region 42 is connected to wirings 61 formed in the wiring layer 33. The power supply voltage VE is supplied to the high-concentration n-type semiconductor region 42 via the wirings 61. That is, the wirings 61 supply the power supply voltage VE for forming the avalanche multiplication region to the high-concentration n-type semiconductor region 42 as a cathode electrode. Note that, although the wirings 61 are not present in the cross section taken along line A-A′ in A of FIG. 3, the wirings 61 are depicted in the plan view of B of FIG. 3 in order to describe a contact portion between the wirings 61 at the front surface interface of the substrate and the high-concentration n-type semiconductor region 42. The illustration of the wirings 61 in the plan view is similar in other drawings to be described later. As depicted in B of FIG. 3, the power supply voltage VE is supplied to the high-concentration n-type semiconductor region 42 as the cathode electrode by, for example, four wirings 61. However, the number of wirings 61 is not limited to four, and may be another number.

The high-concentration p-type semiconductor region 43 in A of FIG. 3 is a thick p-type (second conductivity type) semiconductor region (second semiconductor region) formed by being bonded to the upper surface of the high-concentration n-type semiconductor region 42 in the semiconductor substrate 31. The avalanche multiplication region is formed by a depletion layer formed in a PN junction region where the high-concentration n-type semiconductor region 42 and the high-concentration p-type semiconductor region 43 are joined. A plane shape of the high-concentration n-type semiconductor region 42 is a rectangular shape substantially equivalent to an outer shape size of the high-concentration n-type semiconductor region 44 in B of FIG. 3. A plane shape of the high-concentration p-type semiconductor region 43 is formed to be slightly smaller than a plane size of the high-concentration n-type semiconductor region 42. Thus, the edge breakdown is reduced at the end of the multiplication region.

The high-concentration n-type semiconductor region 44 (third semiconductor region) is formed in the vicinity of the front surface interface of the semiconductor substrate 31 and at a position away from the high-concentration n-type semiconductor region 42 as the cathode electrode by a predetermined distance in a plane direction. The high-concentration n-type semiconductor region 44 functions as a gettering site that is a region for capturing and fixing impurities that cause metal contamination. As depicted in B of FIG. 3, a plane shape of the high-concentration n-type semiconductor region 44 is a rectangular shape having a predetermined width, and it is arranged so as to surround the outer periphery of the high-concentration n-type semiconductor region 42 formed in the central portion of the pixel region. A plane position of the high-concentration n-type semiconductor region 44 is arranged at a position at least partially overlapping the PN junction region between the high-concentration n-type semiconductor region 42 and the high-concentration p-type semiconductor region 43. The impurity concentration of the high-concentration n-type semiconductor region 44 is, for example, the same concentration as that of the high-concentration n-type semiconductor region 42. The high-concentration n-type semiconductor region 44 is not connected to any wiring of the wiring layer 33 and is electrically floating.

Here, the impurity concentration of the n-well 41 is set to a low concentration of, for example, 1E+14/cm³ or less, and the impurity concentration of each of the high-concentration n-type semiconductor region 42 and the high-concentration p-type semiconductor region 43 forming the avalanche multiplication region is set to a high concentration of 1E+16/cm³ or more.

An inter-pixel isolation section 51 penetrating the semiconductor substrate 31 from the front surface side to the back surface side is formed on an outer side of the n-well 41 in the plane direction and at a boundary portion with another adjacent pixel 10. The inter-pixel isolation section 51 includes, for example, a metal material such as tungsten (W), aluminum (Al), titanium (Ti), or titanium nitride (TiN), or a conductive material such as polysilicon, and is electrically separated from another adjacent pixel. The inter-pixel isolation section 51 is formed in a lattice shape along pixel boundaries as a whole of the semiconductor substrate 31 as depicted in B of FIG. 3.

An insulating layer 52, a fixed charge film 53, and a hole accumulation layer 54 are formed in this order on a sidewall in the pixel of the inter-pixel isolation section 51. The insulating layer 52 is formed by, for example, SiO2. The fixed charge film 53 is a negative fixed charge film, and a hole accumulation region is formed inside the fixed charge film 53 by induction of holes by the fixed charge film 53.

The hole accumulation layer 54 includes a p-type semiconductor region (p) and accumulates holes generated by photoelectric conversion. Furthermore, the hole accumulation layer 54 traps electrons generated at the interface with the insulating layer 52 and also has an effect of suppressing a dark count rate (DCR). A dark current can be suppressed and the DCR can be suppressed by the hole accumulation region formed by the fixed charge film 53 and the hole accumulation layer 54 formed inside the hole accumulation region. Furthermore, it is possible to easily collect carriers in a high electric field region by reducing crosstalk and forming a lateral electric field, and it is possible to improve photon detection efficiency (PDE).

A region in the vicinity of the front surface side of the substrate of the hole accumulation layer 54 is particularly controlled to have a high impurity concentration (p+), and is a high-concentration p-type semiconductor region 55 (fourth semiconductor region). The high-concentration p-type semiconductor region 55 is connected to a wiring 62 formed in the wiring layer 33. The power supply voltage VSPAD is applied to the high-concentration p-type semiconductor region 55 via the wiring 62. That is, the wiring 62 supplies the power supply voltage VSPAD to the high-concentration p-type semiconductor region 55 as an anode electrode. The hole accumulation layer 54 can be formed by ion implantation, or may be formed by solid-phase diffusion. In the example of FIG. 3, the hole accumulation layer 54 is formed only on the side surface of the inter-pixel isolation section 51, but may also be formed on the interface on the substrate back surface side which is the light incident surface.

In the pixel 10 according to the first configuration example described above, as depicted in the plan view of B of FIG. 3, the high-concentration n-type semiconductor region 42 as the cathode electrode is formed with a small plane size only at the central portion of the pixel region at the interface on the front surface side of the semiconductor substrate 31. On the other hand, the high-concentration p-type semiconductor region 55 as the anode electrode is formed along an outer peripheral portion of the rectangular pixel region. Thus, a distance DX between the anode and the cathode can be secured wide, and a region of the high-concentration n-type semiconductor region 44 that is the gettering site can be secured. Then, the high-concentration n-type semiconductor region 44 functioning as the gettering site is formed in an electrically floating state between the high-concentration n-type semiconductor region 42 and the high-concentration p-type semiconductor region 55. Thus, an electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Note that, in the example described above, the impurity concentration of the high-concentration n-type semiconductor region 44 functioning as the gettering site is the same as the concentration of the high-concentration n-type semiconductor region 42, but is not necessarily the same, and may be different.

In addition, although the plane shape of the high-concentration n-type semiconductor region 44 functioning as the gettering site is a rectangular shape, the plane shape may be any shape as long as it can be arranged between the high-concentration n-type semiconductor region 42 and the high-concentration p-type semiconductor region 55, and may be, for example, a polygonal shape or an annular shape. In addition, corners of the polygonal shape may have a rounded shape.

The first configuration example depicted in FIG. 3 is an example of a structure in which electrons are read out as signal charges (carriers), but a structure in which holes are read out can also be employed. In this case, the high-concentration n-type semiconductor region 42 is changed to a high-concentration p-type semiconductor region, and the high-concentration p-type semiconductor region 43 is changed to a high-concentration n-type semiconductor region. Furthermore, the high-concentration p-type semiconductor region 55 is changed to a high-concentration n-type semiconductor region. Moreover, the power supply voltage VSPAD is applied from the wirings 61 to the contact portion changed from the high-concentration n-type semiconductor region 42 to the high-concentration p-type semiconductor region, and the power supply voltage VE is applied from the wiring 62 to the contact portion changed from the high-concentration p-type semiconductor region 55 to the high-concentration n-type semiconductor region.

<3. Second Configuration Example of Pixel>

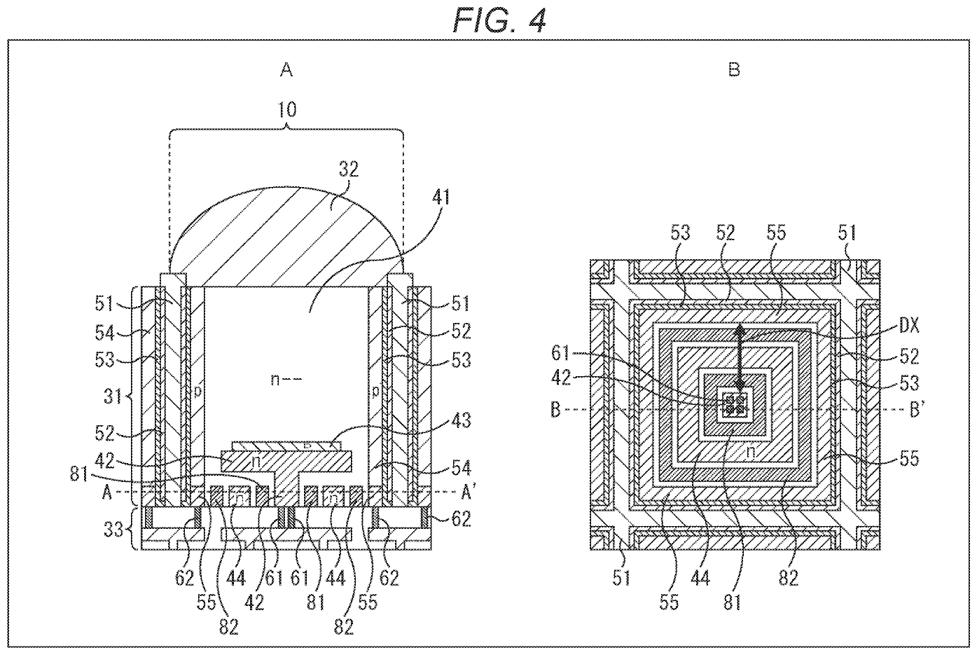

FIG. 4 is a diagram depicting a second configuration example of the pixel 10 using the SPAD 21 described above.

Note that, in the second configuration example to a tenth configuration example depicted in FIG. 4 and subsequent drawings, parts corresponding to those in the first configuration example depicted in FIG. 3 are denoted by the same reference numerals, and description of those parts will be omitted as appropriate.

A of FIG. 4 is a cross-sectional view of the pixel 10 according to the second configuration example, and B of FIG. 4 is a plan view of the pixel 10 according to the second configuration example. The cross-sectional view of A of FIG. 4 is a cross-sectional view taken along line B-B′ of B of FIG. 4, and the plan view of B of FIG. 4 is a plan view taken along line A-A′ of A of FIG. 4.

The second configuration example of FIG. 4 is different from the first configuration example of FIG. 3 in that buried insulating films 81 and 82 are newly provided, and is common to the first configuration example of FIG. 3 in other points. The buried insulating films 81 and 82 are what are called shallow trench isolation (STI).

As depicted in A and B of FIG. 4, the buried insulating film 81 is arranged in a rectangular shape surrounding the high-concentration n-type semiconductor region 42 inside with a predetermined width between the high-concentration n-type semiconductor region 42 that is the cathode electrode and the high-concentration n-type semiconductor region 44 that is the gettering site.

As depicted in A and B of FIG. 4, the buried insulating film 82 is arranged in a rectangular shape surrounding the high-concentration n-type semiconductor region 44 inside with a predetermined width between the high-concentration n-type semiconductor region 44 that is the gettering site and the high-concentration p-type semiconductor region 55 that is the anode electrode.

In the pixel 10 according to the second configuration example described above, as in the first configuration example, the high-concentration n-type semiconductor region 42 as the cathode electrode is formed with a small plane size only at the central portion of the pixel region, and the high-concentration p-type semiconductor region 55 as the anode electrode is formed along the outer peripheral portion of the rectangular pixel region. Thus, the distance DX between the anode and the cathode can be secured wide, and the region of the high-concentration n-type semiconductor region 44 that is the gettering site can be secured. Then, the high-concentration n-type semiconductor region 44 functioning as the gettering site is formed in an electrically floating state between the high-concentration n-type semiconductor region 42 and the high-concentration p-type semiconductor region 55. Thus, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Moreover, the pixel 10 according to the second configuration example includes the buried insulating film 81 between the high-concentration n-type semiconductor region 42 that is the cathode electrode and the high-concentration n-type semiconductor region 44 as the gettering site, and the buried insulating film 82 between the high-concentration n-type semiconductor region 44 as the gettering site and the high-concentration p-type semiconductor region 55 that is the anode electrode. By the physically inserted buried insulating films 81 and 82, the electric field between the cathode and the anode can be further relaxed, and the unintended edge breakdown caused by the narrowing of the distance between the cathode electrode and the anode electrode can be further reduced.

<4. Third Configuration Example of Pixel>

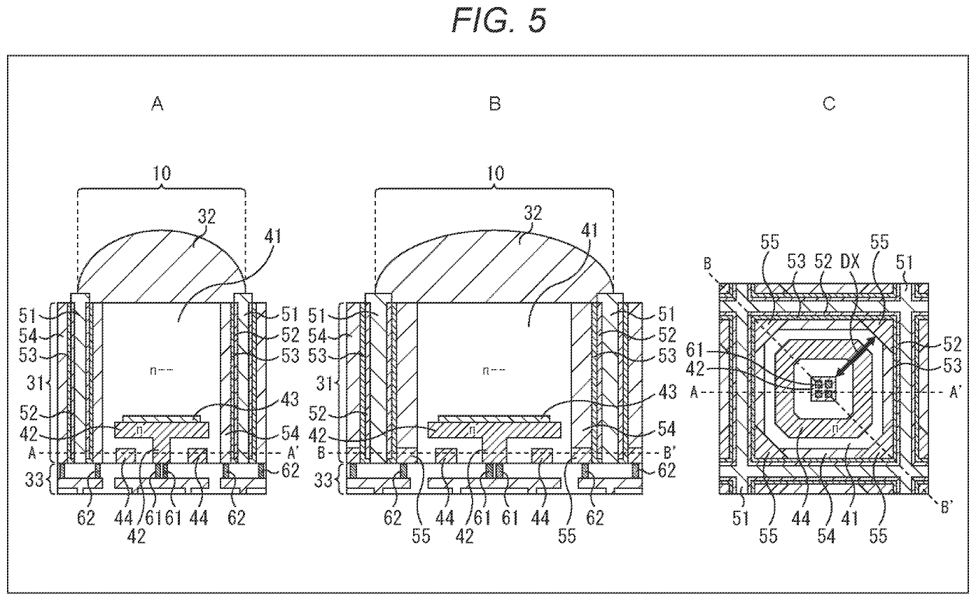

FIG. 5 is a diagram depicting a third configuration example of the pixel 10 using the SPAD 21 described above.

A and B of FIG. 5 are cross-sectional views of the pixel 10 according to the third configuration example, and C of FIG. 5 is a plan view of the pixel 10 according to the third configuration example. The cross-sectional view of A of FIG. 5 is a cross-sectional view taken along line A-A′ of C of FIG. 5, the cross-sectional view of B of FIG. 5 is a cross-sectional view taken along line B-B′ of C of FIG. 5, and the plan view of C of FIG. 5 is a plan view taken along line A-A′ of A of FIG. 5 and line B-B′ of B of FIG. 5.

The third configuration example of FIG. 5 is different from the first configuration example depicted in FIG. 3 in the formation position of the high-concentration p-type semiconductor region 55 as the anode electrode. That is, the high-concentration p-type semiconductor region 55 is formed on the entire outer peripheral portion of the rectangular pixel region as depicted in B of FIG. 3 in the first configuration example, but is formed in a triangular shape at each of corner portions of four corners of the rectangular pixel region in the third configuration example of FIG. 5.

The high-concentration n-type semiconductor region 44 functioning as the gettering site has a rectangular shape in which each of the corner portions of the four corners are obliquely cut in plan view. Thus, the distance between the high-concentration p-type semiconductor region 55 and the high-concentration n-type semiconductor region 44 arranged at the corner portions of the four corners is kept constant.

The configuration other than the high-concentration p-type semiconductor region 55 and the high-concentration n-type semiconductor region 44 described above is similar to that of the first configuration example depicted in FIG. 3.

Also in the pixel 10 according to the third configuration example, as in the first configuration example, the distance DX between the anode and the cathode can be secured wider, and the region of the high-concentration n-type semiconductor region 44 as the gettering site can be secured. Then, the high-concentration n-type semiconductor region 44 is formed in an electrically floating state, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

In the third configuration example, the high-concentration p-type semiconductor region 55 that is the anode electrode is arranged in a triangular shape at each of the corner portions of the four corners of the rectangular pixel region, so that the distance from the high-concentration n-type semiconductor region 42 that is the cathode electrode can be secured wider. Furthermore, since the high-concentration p-type semiconductor region 55 as the anode electrode does not exist at side central portions of the outer peripheral portion of the rectangular pixel region, the region of the high-concentration n-type semiconductor region 44 as the gettering site can be expanded to the outer peripheral portion, and the region of the gettering site can be expanded.

<5. Fourth Configuration Example of Pixel>

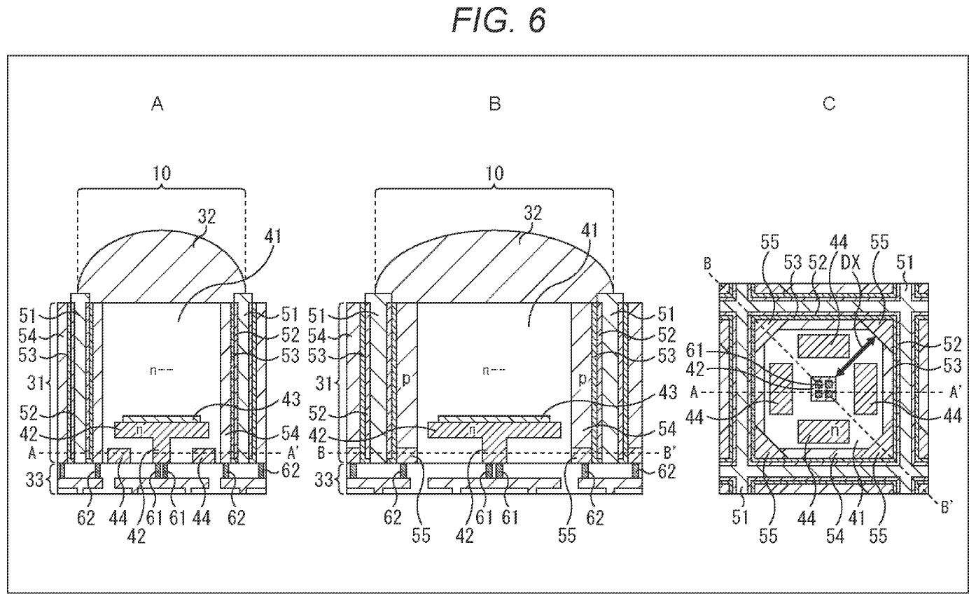

FIG. 6 is a diagram depicting a fourth configuration example of the pixel 10 using the SPAD 21 described above.

A and B of FIG. 6 are cross-sectional views of the pixel 10 according to the fourth configuration example, and C of FIG. 6 is a plan view of the pixel 10 according to the fourth configuration example. The cross-sectional view of A of FIG. 6 is a cross-sectional view taken along line A-A′ of C of FIG. 6, the cross-sectional view of B of FIG. 6 is a cross-sectional view taken along line B-B′ of C of FIG. 6, and the plan view of C of FIG. 6 is a plan view taken along line A-A′ of A of FIG. 6 and line B-B′ of B of FIG. 6.

The fourth configuration example of FIG. 6 is different from the third configuration example depicted in FIG. 5 in the formation position of the high-concentration n-type semiconductor region 44 as the gettering site. That is, in the third configuration example, as depicted in B of FIG. 5, the high-concentration n-type semiconductor region 44 is formed as one region surrounding the high-concentration n-type semiconductor region 42 as the cathode electrode formed in the central portion of the rectangular pixel region, but in the fourth configuration example of FIG. 6, as depicted in C of FIG. 6, the high-concentration n-type semiconductor region is divided into four regions on the outer side in the longitudinal direction and the lateral direction of the high-concentration n-type semiconductor region 42 in the central portion of the pixel region. The fourth configuration example is similar to the third configuration example depicted in FIG. 5 except for the formation position of the high-concentration n-type semiconductor region 44.

As in the fourth configuration example of FIG. 6, the high-concentration n-type semiconductor region 44 as the gettering site is not limited to the arrangement surrounding the entire outer periphery of the high-concentration n-type semiconductor region 42 as the cathode electrode formed in the central portion of the pixel region. In the example of FIG. 6, the high-concentration n-type semiconductor region 44 is arranged on the outer side in the vertical direction and the horizontal direction of the high-concentration n-type semiconductor region 42 in the central portion of the pixel region, but may be arranged on the outer side in a diagonally rising rightward direction and a diagonally rising leftward direction that are diagonal directions of the rectangular pixel region.

Also in the pixel 10 according to the fourth configuration example, as in the third configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Furthermore, since the high-concentration p-type semiconductor region 55 as the anode electrode is arranged in a triangular shape at each of the corner portions of the four corners of the rectangular pixel region, the region of the high-concentration n-type semiconductor region 44 as the gettering site can be expanded to the outer peripheral portion, and the region of the gettering site can be expanded.

<6. Fifth Configuration Example of Pixel>

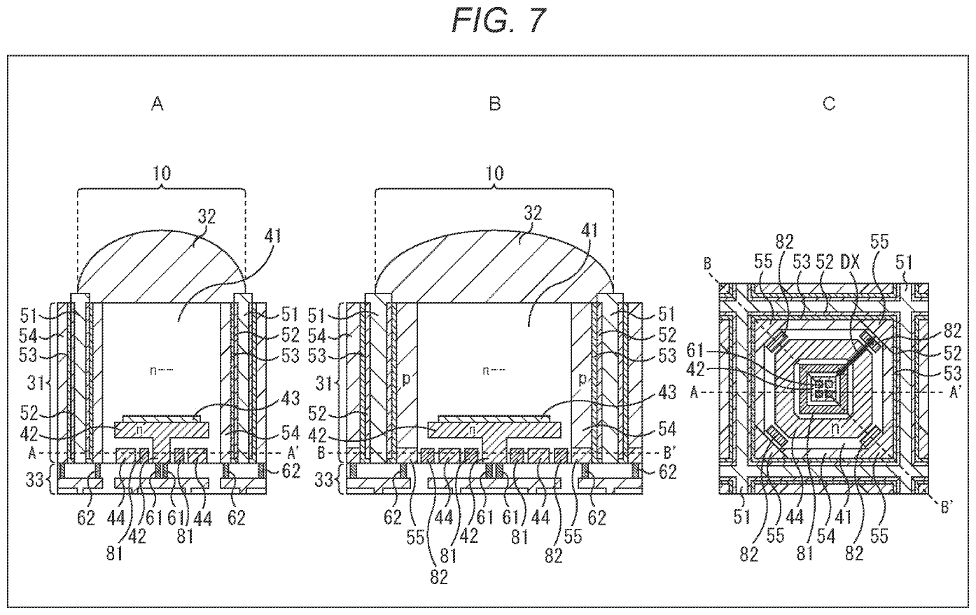

FIG. 7 is a diagram depicting a fifth configuration example of the pixel 10 using the SPAD 21 described above.

A and B of FIG. 7 are cross-sectional views of the pixel 10 according to the fifth configuration example, and C of FIG. 7 is a plan view of the pixel 10 according to the fifth configuration example. The cross-sectional view of A of FIG. 7 is a cross-sectional view taken along line A-A′ of C of FIG. 7, the cross-sectional view of B of FIG. 7 is a cross-sectional view taken along line B-B′ of C of FIG. 7, and the plan view of C of FIG. 7 is a plan view taken along line A-A′ of A of FIG. 7 and line B-B′ of B of FIG. 7.

The fifth configuration example of FIG. 7 has a configuration in which the buried insulating films 81 and 82 similar to those in the second configuration example of FIG. 4 are newly added to the third configuration example depicted in FIG. 5. However, the second configuration example of FIG. 4 is a configuration in which the high-concentration p-type semiconductor region 55 as the anode electrode is arranged on the entire outer peripheral portion of the rectangular pixel region, whereas the fifth configuration example of FIG. 7 is a configuration in which the high-concentration p-type semiconductor region 55 as the anode electrode is arranged in a triangular shape at each of the corner portions of the four corners of the rectangular pixel region. Thus, the buried insulating film 82 is formed not in the entire outer periphery of the high-concentration n-type semiconductor region 44 but only in diagonal directions in which the high-concentration p-type semiconductor region 55 is formed.

That is, the buried insulating film 81 is arranged in a rectangular shape surrounding the high-concentration n-type semiconductor region 42 inside with a predetermined width between the high-concentration n-type semiconductor region 42 as the cathode electrode and the high-concentration n-type semiconductor region 44 as the gettering site.

The buried insulating film 82 is arranged by dividing into four regions in the diagonal directions of the pixel region between the high-concentration n-type semiconductor region 44 as the gettering site and the high-concentration p-type semiconductor region 55 as the anode electrode.

Also in the pixel 10 according to the fifth configuration example, as in the fourth configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Furthermore, since the high-concentration p-type semiconductor region 55 that is the anode electrode is arranged in a triangular shape at each of the corner portions of the four corners of the rectangular pixel region, the region of the high-concentration n-type semiconductor region 44 that is the gettering site can be expanded to the outer peripheral portion, and the region of the gettering site can be expanded.

Moreover, the buried insulating film 81 is provided between the high-concentration n-type semiconductor region 42 as the cathode electrode and the high-concentration n-type semiconductor region 44 as the gettering site, and the buried insulating film 82 is provided between the high-concentration n-type semiconductor region 44 as the gettering site and the high-concentration p-type semiconductor region 55 as the anode electrode, so that the electric field between the cathode and the anode can be further relaxed, and unintended edge breakdown can be further reduced.

<7. Sixth Configuration Example of Pixel>

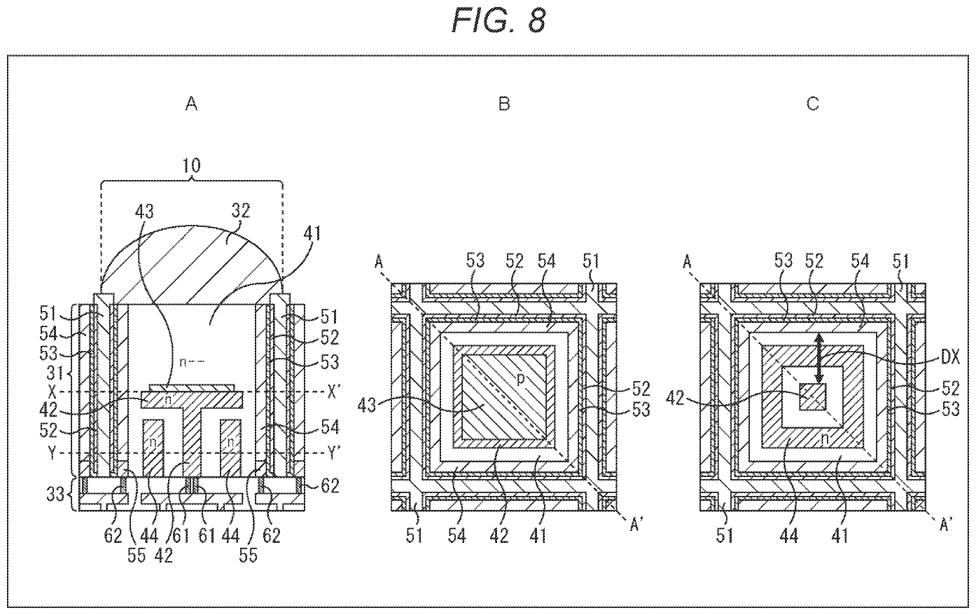

FIG. 8 is a diagram depicting a sixth configuration example of the pixel 10 using the SPAD 21 described above.

A of FIG. 8 is a cross-sectional view of the pixel 10 according to the sixth configuration example, and B and C of FIG. 8 are plan views of the pixel 10 according to the sixth configuration example. The cross-sectional view of A of FIG. 8 illustrates a cross-sectional view taken along line A-A′ of B and C of FIG. 8, the plan view of B of FIG. 8 illustrates a plan view taken along line X-X′ of A of FIG. 8, and the plan view of C of FIG. 8 illustrates a plan view taken along line Y-Y′ of A of FIG. 8.

In the sixth configuration example of FIG. 8, the position in the substrate depth direction of the PN junction region of the high-concentration n-type semiconductor region 42 and the high-concentration p-type semiconductor region 43 forming the avalanche multiplication region is formed at a deeper position in the substrate as compared with the first configuration example depicted in FIG. 3. Furthermore, along with the change of the substrate depth position of the PN junction region, the high-concentration n-type semiconductor region 44 as the gettering site is also formed from the front surface of the substrate to a deeper position in the substrate. The substrate depth position of the PN junction region of the high-concentration n-type semiconductor region 42 and the high-concentration p-type semiconductor region 43 can be, for example, a position corresponding to about ¼ to ½ of the substrate thickness from the front surface of the semiconductor substrate 31. Other configurations of the pixel 10 according to the sixth configuration example are similar to those of the first configuration example depicted in FIG. 3.

By forming the PN junction region of the high-concentration n-type semiconductor region 42 and the high-concentration p-type semiconductor region 43 forming the avalanche multiplication region at a deep position of the semiconductor substrate 31, the high-concentration n-type semiconductor region 44 functioning as the gettering site can also be formed deep in the substrate depth direction, so that the gettering site can be formed not only in the substrate surface but also in the depth direction.

Also in the sixth configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

<8. Seventh Configuration Example of Pixel>

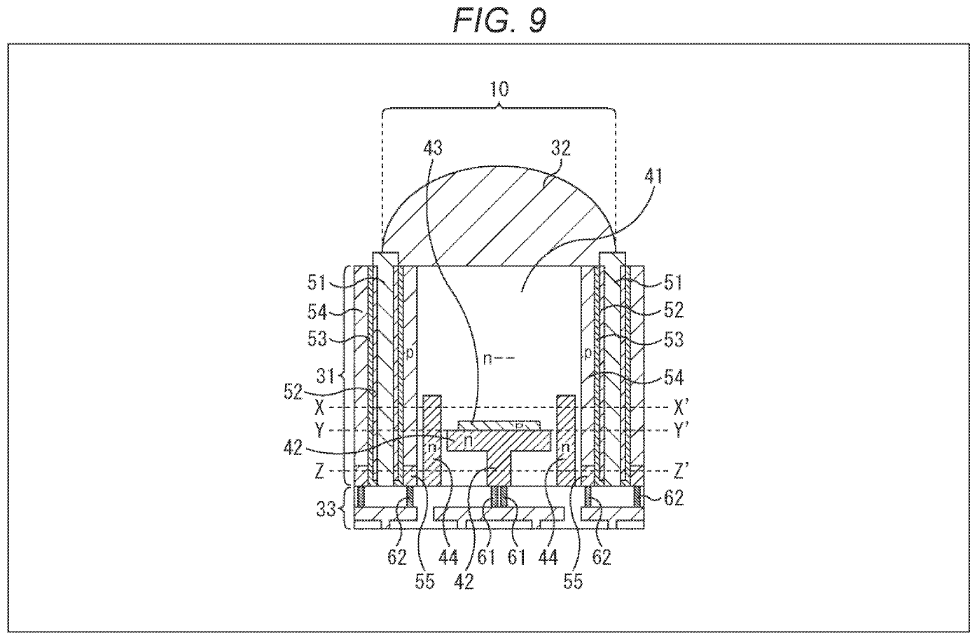

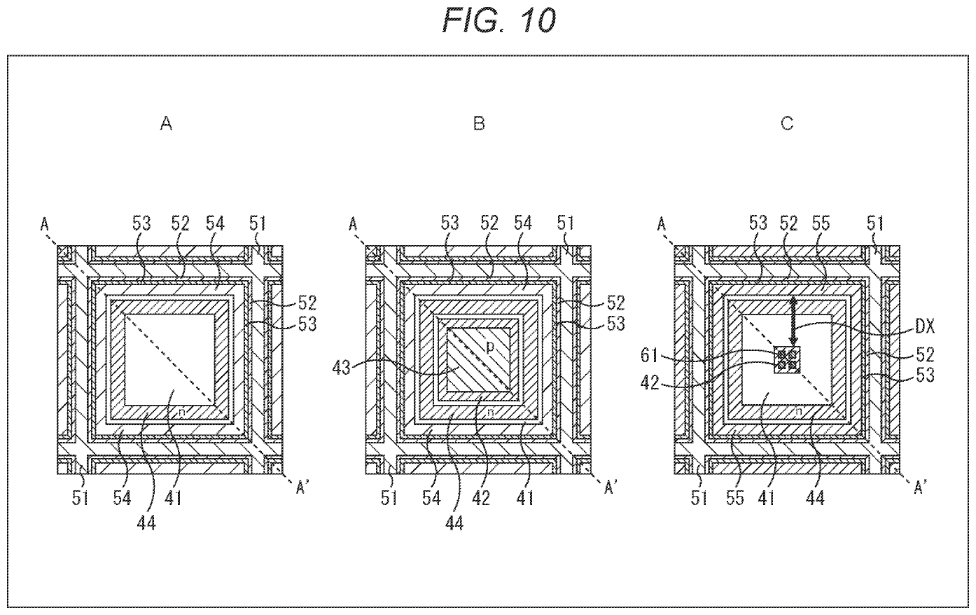

FIGS. 9 and 10 are diagrams depicting a seventh configuration example of the pixel 10 using the SPAD 21 described above.

FIG. 9 is a cross-sectional view of the pixel 10 according to the seventh configuration example, and FIG. 10 is a plan view of the pixel 10 according to the seventh configuration example. A cross-sectional view of FIG. 9 is a cross-sectional view taken along line A-A′ of FIG. 10, a plan view of A of FIG. 10 is a plan view taken along line X-X′ of FIG. 9, a plan view of B of FIG. 10 is a plan view taken along line Y-Y′ of FIG. 9, and a plan view of C of FIG. 10 is a plan view taken along line Z-Z′ of FIG. 9.

The seventh configuration example of FIG. 9 is common to the sixth configuration example of FIG. 8 in that the high-concentration n-type semiconductor region 44 functioning as the gettering site is formed deep in the substrate depth direction. Thus, the gettering site can be formed not only on the substrate surface but also in the depth direction.

On the other hand, in the sixth configuration example of FIG. 8, the high-concentration n-type semiconductor region 44 as the gettering site is at a position shallower than the depth position of the PN junction region of the high-concentration n-type semiconductor region 42 and the high-concentration p-type semiconductor region 43 forming the avalanche multiplication region, whereas the seventh configuration example of FIG. 9 is different from the sixth configuration example of FIG. 8 in that it is formed to a position deeper than the depth position of the PN junction region.

Furthermore, the high-concentration n-type semiconductor region 44 of the sixth configuration example of FIG. 8 is arranged at a position at least partially overlapping the PN junction region in plan view. On the other hand, as depicted in B of FIG. 10, the high-concentration n-type semiconductor region 44 of the seventh configuration example is arranged outside the PN junction region in plan view.

Other configurations of the pixel 10 according to the seventh configuration example are similar to those of the sixth configuration example in FIG. 8.

Also in the seventh configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

<9. Eighth Configuration Example of Pixel>

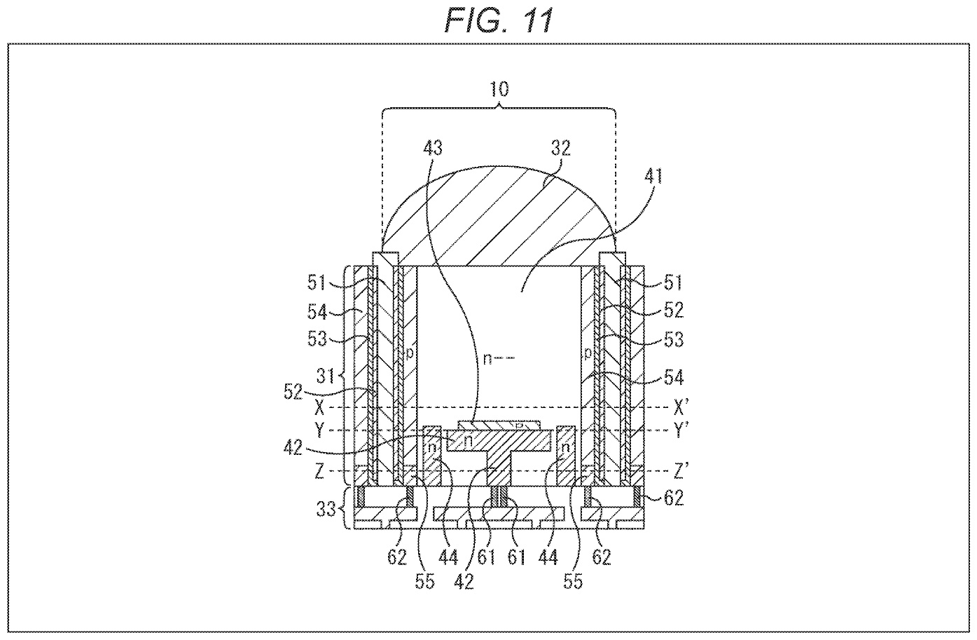

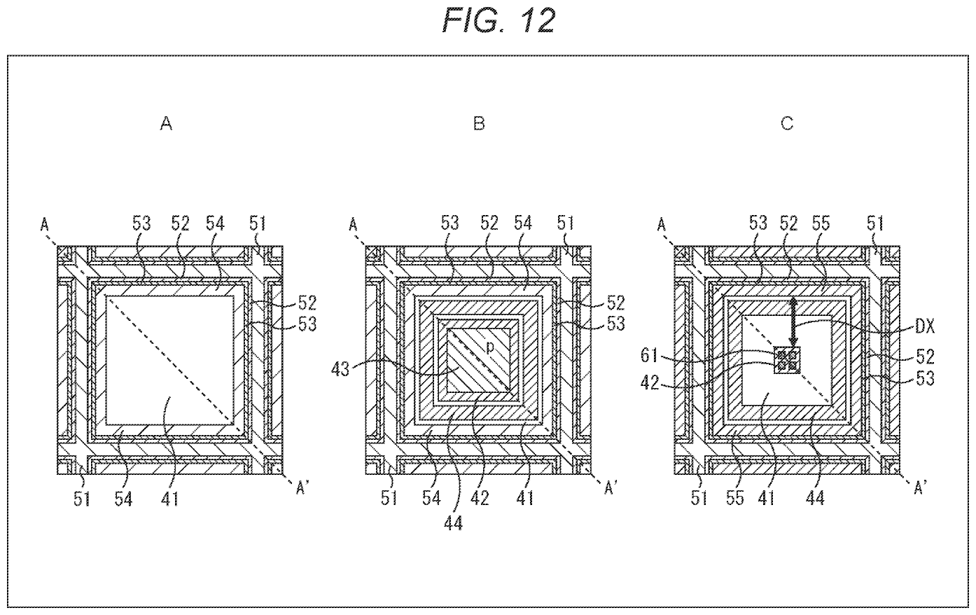

FIGS. 11 and 12 are diagrams depicting an eighth configuration example of the pixel 10 using the SPAD 21 described above.

FIG. 11 is a cross-sectional view of the pixel 10 according to the eighth configuration example, and FIG. 12 is a plan view of the pixel 10 according to the eighth configuration example. A cross-sectional view of FIG. 11 is a cross-sectional view taken along line A-A′ of FIG. 12, a plan view of A of FIG. 12 is a plan view taken along line X-X′ of FIG. 11, a plan view of B of FIG. 12 is a plan view taken along line Y-Y′ of FIG. 11, and a plan view of C of FIG. 12 is a plan view taken along line Z-Z′ of FIG. 11.

The eighth configuration example of FIG. 11 is common to the seventh configuration example of FIG. 9 in that the high-concentration n-type semiconductor region 44 functioning as the gettering site is formed deep in the substrate depth direction. Thus, the gettering site can be formed not only on the substrate surface but also in the depth direction.

On the other hand, a difference between the eighth configuration example of FIG. 11 and the seventh configuration example depicted in FIG. 9 is that the high-concentration n-type semiconductor region 44 of the seventh configuration example depicted in FIG. 9 is formed to a position deeper than the PN junction region, whereas the eighth configuration example of FIG. 11 has the same depth as the PN junction region. Note that it is not necessary to be completely the same as the depth of the PN junction region, and is only required to be substantially the same as the depth of the PN junction region.

In other words, the position of the high-concentration n-type semiconductor region 44 in the substrate depth direction is formed deeper than the high-concentration p-type semiconductor region 43 in the seventh configuration example depicted in FIG. 9, whereas the position does not exceed the depth of the high-concentration p-type semiconductor region 43 constituting the PN junction region in the eighth configuration example of FIG. 11.

Other configurations of the pixel 10 according to the eighth configuration example are similar to those of the seventh configuration example.

Also in the eighth configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

<10. Ninth Configuration Example of Pixel>

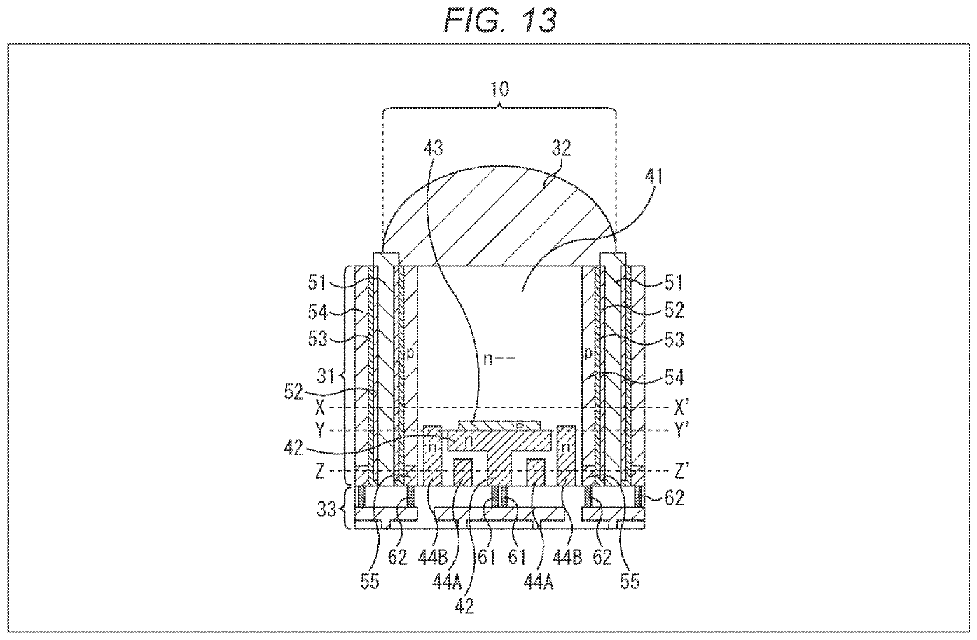

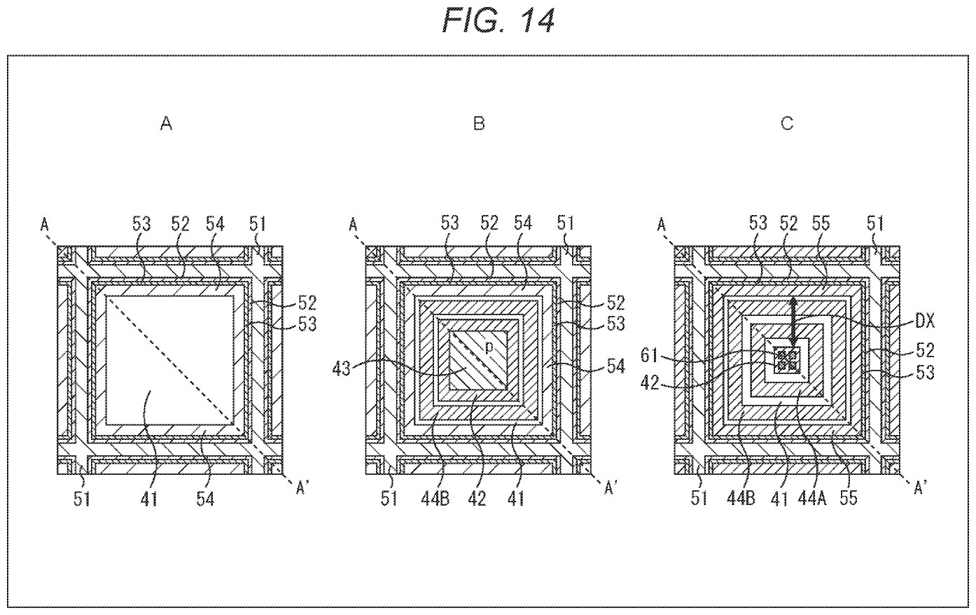

FIGS. 13 and 14 are diagrams depicting a ninth configuration example of the pixel 10 using the SPAD 21 described above.

FIG. 13 is a cross-sectional view of the pixel 10 according to the ninth configuration example, and FIG. 14 is a plan view of the pixel 10 according to the ninth configuration example. A cross-sectional view of FIG. 13 is a cross-sectional view taken along line A-A′ of FIG. 14, a plan view of A of FIG. 14 is a plan view taken along line X-X′ of FIG. 13, a plan view of B of FIG. 14 is a plan view taken along line Y-Y′ of FIG. 13, and a plan view of C of FIG. 14 is a plan view taken along line Z-Z′ of FIG. 13.

The ninth configuration example of FIGS. 13 and 14 has a configuration including both the high-concentration n-type semiconductor region 44 of the first configuration example depicted in FIG. 3 and the high-concentration n-type semiconductor region 44 of the eighth configuration example depicted in FIG. 11.

That is, as in the first configuration example depicted in FIG. 3, the high-concentration n-type semiconductor region 44A in the ninth configuration example is arranged at a position at least partially overlapping the PN junction region of the high-concentration n-type semiconductor region 42 and the high-concentration p-type semiconductor region 43 forming the avalanche multiplication region in plan view.

On the other hand, as in the eighth configuration example depicted in FIG. 11, the high-concentration n-type semiconductor region 44B in the ninth configuration example is arranged outside the PN junction region of the high-concentration n-type semiconductor region 42 and the high-concentration p-type semiconductor region 43 forming the avalanche multiplication region in plan view, and is formed to substantially the same depth as the PN junction region in cross-sectional view. Note that the position in the depth direction may be formed deeper than the PN junction region as in the seventh configuration example depicted in FIG. 9. That is, the position in the depth direction of the high-concentration n-type semiconductor region 44B is only required to be at least substantially the same depth as the PN junction region.

Other configurations of the pixel 10 according to the ninth configuration example are similar to those of the eighth configuration example depicted in FIGS. 11 and 12.

Also in the ninth configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Moreover, by forming the high-concentration n-type semiconductor region 44A arranged on the outer periphery of the high-concentration n-type semiconductor region 42 in the region near the front surface of the substrate and the high-concentration n-type semiconductor region 44B having substantially the same depth as the avalanche multiplication region on the outer periphery of the avalanche multiplication region, the region of the gettering site is increased, and the gettering effect can be further obtained.

<11. Tenth Configuration Example of Pixel>

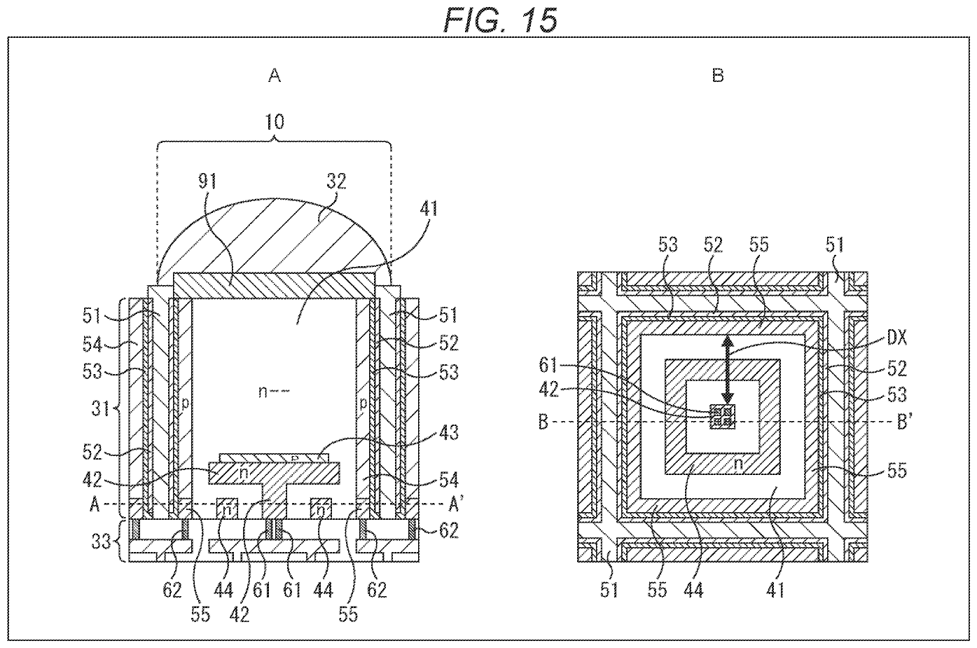

FIG. 15 is a diagram depicting a tenth configuration example of the pixel 10 using the SPAD 21 described above.

A of FIG. 15 is a cross-sectional view of the pixel 10 according to the tenth configuration example, and B of FIG. 15 is a plan view of the pixel 10 according to the tenth configuration example. The cross-sectional view of A of FIG. 15 is a cross-sectional view taken along line B-B′ of B of FIG. 15, and the plan view of B of FIG. 15 is a plan view taken along line A-A′ of A of FIG. 15.

The tenth configuration example of FIG. 15 is different from the first configuration example of FIG. 3 in that a color filter 91 that transmits a wavelength corresponding to a predetermined color such as red (R), green (G), or blue (G) is formed on the back surface side of the semiconductor substrate 31, and an on-chip lens 32 is formed on the color filter 91, and is the same as the first configuration example of FIG. 3 in other points. The color array of the color filters 91 is, for example, what is called a Bayer array, but the array format is not limited to the Bayer array. Furthermore, the type of color is not limited to R, G, and B, and may be other colors such as cyan (C), magenta (M), and yellow (Y). The color filter 91 transmits both visible light of a predetermined color and infrared light.

Other configurations of the pixel 10 according to the tenth configuration example are similar to those of the first configuration example in FIG. 3.

With the pixel 10 according to the tenth configuration example, during a predetermined exposure period, the number of photons transmitted through the color filter 91 such as R, G, and B and received is counted, and the counted value is output as a luminance value, whereby the pixel can also be used as an image sensor that outputs data for viewing. In addition, since the color filter 91 also transmits infrared light, it is also possible to output distance measurement data as a distance measuring sensor.

Also in the tenth configuration example, the distance DX between the anode and the cathode can be secured wider, and the region of the high-concentration n-type semiconductor region 44 as the gettering site can be secured. Then, by the high-concentration n-type semiconductor region 44 formed to be in an electrically floating state functioning as the gettering site, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

<12. Configuration Example of Distance Measuring System>

Next, a distance measuring sensor and a distance measuring system that employ the pixels 10 according to the first to tenth configuration examples described above will be described.

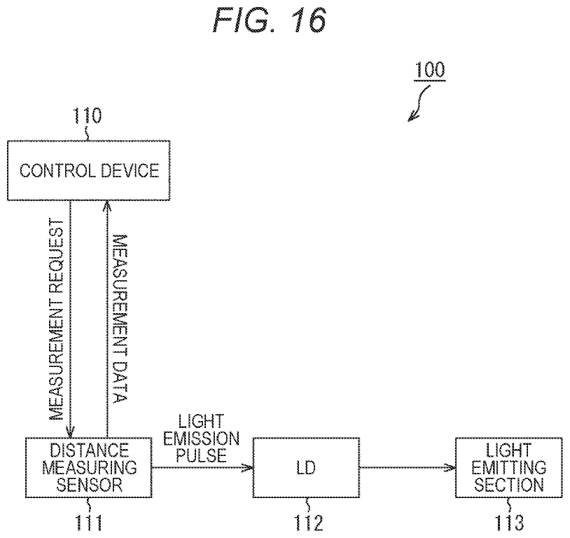

FIG. 16 is a block diagram depicting a configuration example of a distance measuring system employing the pixels 10 according to the first to tenth configuration examples described above.

A distance measuring system 100 in FIG. 16 includes a control device 110, a distance measuring sensor 111, an LD 112, and a light emitting section 113.

The control device 110 is a device that controls the distance measuring sensor 111. For example, the control device 110 supplies a measurement request for requesting execution of measurement to the distance measuring sensor 111 on the basis of a command from a high-order host device. Then, the control device 110 obtains measurement data, which is a result of execution by the distance measuring sensor 111 in response to the measurement request, from the distance measuring sensor 111.

In response to the measurement request from the control device 110, the distance measuring sensor 111 executes measurement of the distance to the subject by, for example, the ToF method, and outputs measurement data as a result to the control device 110. The distance measuring sensor 111 is a light receiving element including a pixel 10 having any one of the first to tenth configuration examples described above.

At the time of measurement, the distance measuring sensor 111 controls the light emitting section 113 as necessary to emit irradiation light. When the irradiation light is emitted, the distance measuring sensor 111 supplies a predetermined light emission pulse to the LD 112. The LD 112 is a laser driver that drives the light emitting section 113, drives the light emitting section 113 on the basis of the light emission pulse from the distance measuring sensor 111, and causes the light emitting section 113 to output the irradiation light. The light emitting section 113 includes, for example, a vertical cavity surface emitting laser (VCSEL) LED or the like, and emits irradiation light by driving the LD 112. As the irradiation light, for example, infrared light (IR light) having a wavelength in a range of about 850 nm to 940 nm is used.

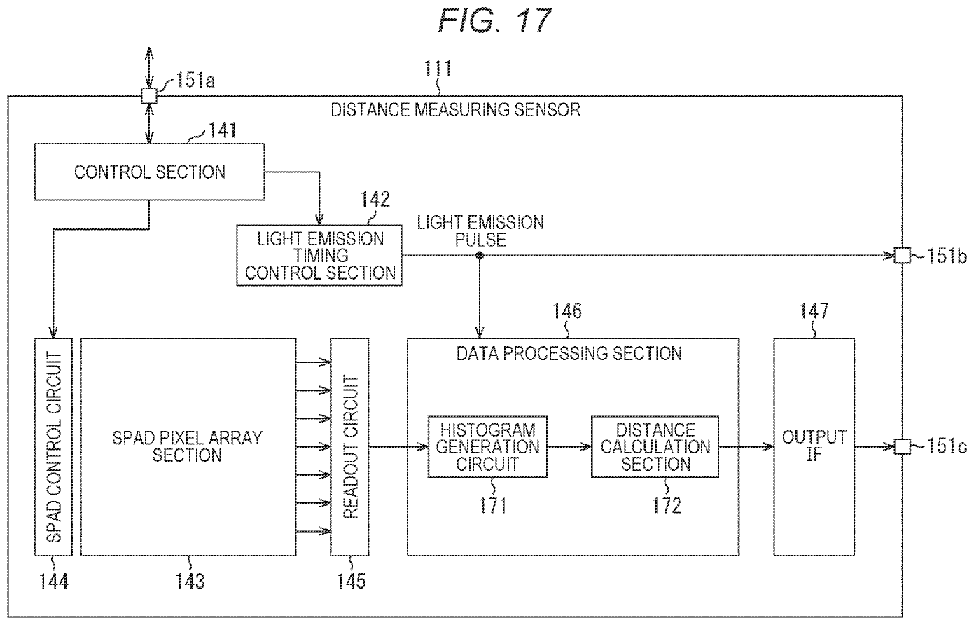

FIG. 17 is a block diagram depicting a first configuration example of the distance measuring sensor 111.

The first configuration example depicted in FIG. 17 is a configuration in a case where the distance measuring sensor 111 includes any of the first to ninth configuration examples described above as the pixel 10.

The distance measuring sensor 111 includes a control section 141, a light emission timing control section 142, a SPAD pixel array section 143, a SPAD control circuit 144, a readout circuit 145, a data processing section 146, an output IF 147, and input-output terminals 151a to 151c.

The control section 141 controls the entire operation of the distance measuring sensor 111. For example, the control section 141 performs predetermined communication, such as reception of a measurement request and transmission of measurement data, with the control device 110. The distance measuring sensor 111 can operate all the pixels 10 in the SPAD pixel array section 143 (active pixels) or can operate only part of the pixels 10 of a plurality of lines or the like. The control section 141 supplies an active control signal for controlling which pixel 10 in the SPAD pixel array section 143 is operated to the SPAD control circuit 144.

The light emission timing control section 142 generates a light emission pulse for controlling the light emission timing of the irradiation light on the basis of the control from the control section 141, and outputs the light emission pulse to the LD 112 via the input-output terminal 151b. Furthermore, the light emission timing control section 142 also supplies the generated light emission pulse to the data processing section 146.

The SPAD pixel array section 143 includes a plurality of pixels 10 two-dimensionally arranged in a matrix, and supplies a pixel signal corresponding to the reflected light detected in each pixel 10 to the readout circuit 145. Any of the first to ninth configuration examples described above is employed as the configuration of the pixel 10.

The SPAD control circuit 144 switches an active pixel or an inactive pixel for each pixel 10 of the SPAD pixel array section 143 on the basis of the active control signal supplied from the control section 141. The active pixel is a pixel that detects incidence of a photon, and the inactive pixel is a pixel that does not detect incidence of a photon. Therefore, the SPAD control circuit 144 controls on and off of the light receiving operation of each pixel 10 of the SPAD pixel array section 143. For example, the SPAD control circuit 144 performs control to set at least a part of the plurality of pixels 10 of the SPAD pixel array section 143 as active pixels and the remaining pixels 10 as inactive pixels at a predetermined timing in accordance with the light emission pulse from the light emission timing control section 142. Of course, all the pixels 10 of the SPAD pixel array section 143 may be active pixels.

The readout circuit 145 supplies the pixel signal supplied from each pixel 10 of the SPAD pixel array section 143 to the data processing section 146.

The data processing section 146 includes a histogram generation circuit 171 and a distance calculation section 172.

The histogram generation circuit 171 creates a histogram of the flight time (count value) until the reflected light is received for each pixel on the basis of the emission of the irradiation light repeatedly executed a predetermined number of times (for example, several to several hundred times) and the reception of the reflected light. Data regarding the created histogram (hereinafter referred to as histogram data) is supplied to the distance calculation section 172. The distance calculation section 172 performs noise removal, histogram peak detection, and the like on the histogram data supplied from the histogram generation circuit 171. Then, the distance calculation section 172 calculates the flight time until the light emitted from the light emitting section 113 is reflected by the subject and returned on the basis of a detected peak value of the histogram, and calculates the distance to the subject for each pixel from the calculated flight time. Data of the calculated distance is supplied to the output IF 147.

The output IF 147 stores the data of the distance to the subject calculated for each pixel in a predetermined data format, and outputs the data to the control device 110 via the input-output terminal 151c as measurement data.

The distance measuring sensor 111 in FIG. 17 has the above configuration, and outputs a result of measuring the distance to the subject in response to the measurement request from the control device 110 to the control device 110 as measurement data.

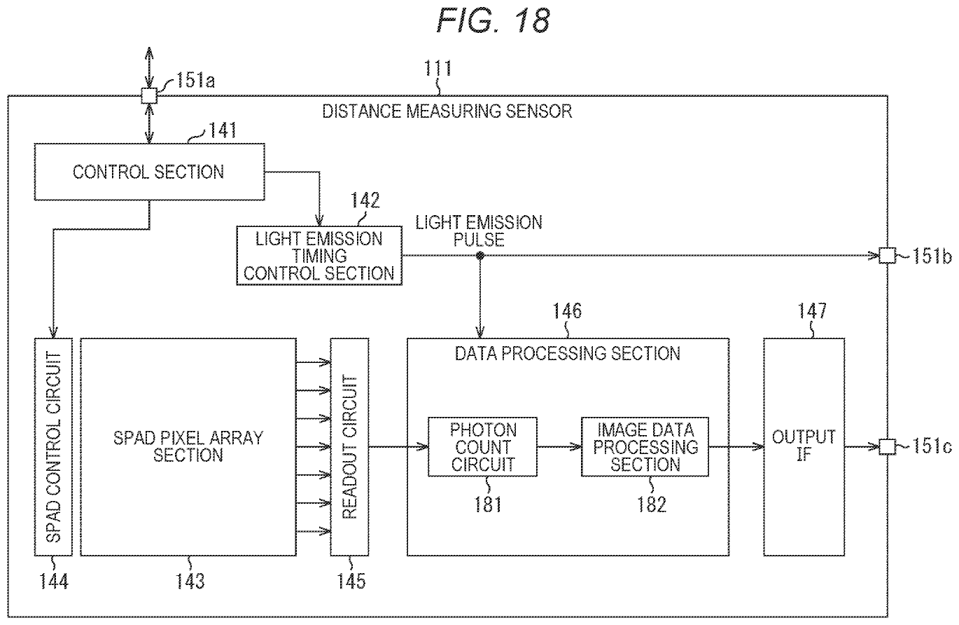

FIG. 18 is a block diagram depicting a second configuration example of the distance measuring sensor 111.

The second configuration example depicted in FIG. 18 is a configuration in a case where the distance measuring sensor 111 has the above-described tenth configuration example as the pixel 10.

The distance measuring sensor 111 according to the second configuration example of FIG. 18 is different from the distance measuring sensor 111 according to the first configuration example depicted in FIG. 17 in the configuration of the data processing section 146, and the others are the same.

In the second configuration example of FIG. 18, the data processing section 146 includes a photon count circuit 181 and an image data processing section 182.

The photon count circuit 181 counts, for each pixel, the number of times the SPAD of each pixel 10 in the SPAD pixel array section 143 has reacted, that is, the number of times the photon is incident within a predetermined period. Then, the photon count circuit 181 supplies the counting result to the image data processing section 182. The image data processing section 182 generates image data (viewing data) in which the counting result of photons measured in each pixel 10 is set to a pixel value (luminance value) according to the received light amount, and supplies the image data to the output IF 147.

The output IF 147 stores the viewing data calculated for each pixel in a predetermined data format, and outputs the viewing data as measurement data to the control device 110 via the input-output terminal 151c.

The distance measuring sensor 111 in FIG. 18 has the above configuration, and outputs image data having a pixel value (luminance value) corresponding to the amount of received light to the control device 110 as measurement data in response to the measurement request from the control device 110.

The distance measuring sensor 111 in FIGS. 17 and 18 includes any one of the pixels 10 according to the first to tenth configuration examples as pixels two-dimensionally arranged in a matrix in the SPAD pixel array section 143. Thus, the electric field between the cathode and the anode can be relaxed, and generation of electrons to be a dark current component can be prevented. Furthermore, it is possible to reduce unintended edge breakdowns caused by narrowing the distance between the cathode and the anode when the pixel 10 is miniaturized.

Therefore, highly accurate measurement data with suppressed noise can be output as a measurement result.

Note that, although not depicted, the data processing section 146 of the distance measuring sensor 111 may include the histogram generation circuit 171 and the distance calculation section 172, and the photon count circuit 181 and the image data processing section 182. In this case, the distance measurement data and the viewing data can be executed in a time division manner and output as the measurement data.

<13. Configuration Example of Electronic Device>

The distance measuring system 100 in FIG. 16 can be mounted on electronic devices such as a smartphone, a tablet terminal, a mobile phone, a personal computer, a game device, a television receiver, a wearable terminal, a digital still camera, and a digital video camera, for example.

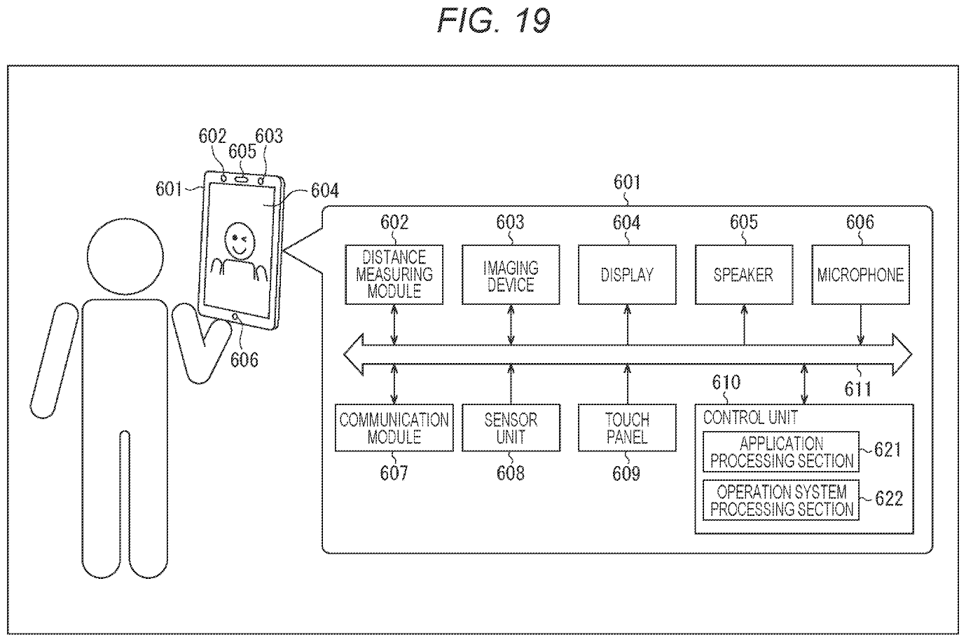

FIG. 19 is a block diagram depicting a configuration example of a smartphone in which the distance measuring system 100 in FIG. 16 is mounted as a distance measuring module.

As depicted in FIG. 19, a smartphone 601 is configured by connecting a distance measuring module 602, an imaging device 603, a display 604, a speaker 605, a microphone 606, a communication module 607, a sensor unit 608, a touch panel 609, and a control unit 610 via a bus 611. Furthermore, the control unit 610 has functions as an application processing section 621 and an operation system processing section 622 by the CPU executing a program.

The distance measuring system 100 in FIG. 16 is applied to the distance measuring module 602. For example, the distance measuring module 602 is arranged in front of the smartphone 601, and performs distance measurement for the user of the smartphone 601, so that the depth value of the surface shape of the face, hand, finger, or the like of the user can be output as a distance measurement result.

The imaging device 603 is arranged on the front surface of the smartphone 601, and performs imaging of the user of the smartphone 601 as a subject to obtain an image in which the user is imaged. Note that, although not depicted, the imaging device 603 may also be arranged on a rear surface of the smartphone 601.

The display 604 displays an operation screen for performing processing by the application processing section 621 and the operation system processing section 622, an image captured by the imaging device 603, and the like. The speaker 605 and the microphone 606 output the voice of the other party and collect the voice of the user, for example, when making a call using the smartphone 601.

The communication module 607 performs communication via a communication network. The sensor unit 608 senses speed, acceleration, proximity and the like, and the touch panel 609 obtains a touch operation by the user on an operation screen displayed on the display 604.

The application processing section 621 performs processing for providing various services by the smartphone 601. For example, the application processing section 621 can perform processing of creating a face by computer graphics virtually reproducing the expression of the user on the basis of a depth supplied from the distance measuring module 602 and displaying the face on the display 604. Furthermore, the application processing section 621 can perform processing of creating three-dimensional shape data of an arbitrary three-dimensional object on the basis of the depth supplied from the distance measuring module 602, for example.

The operation system processing section 622 performs processing for achieving basic functions and operations of the smartphone 601. For example, the operation system processing section 622 can perform processing of authenticating the user's face, and unlocking the smartphone 601 on the basis of the depth value supplied from the distance measuring module 602. Furthermore, the operation system processing section 622 can perform, for example, processing of recognizing a gesture of the user on the basis of the depth value supplied from the distance measuring module 602, and processing of inputting various operations according to the gesture.

In the smartphone 601 configured as described above, by applying the above-described distance measuring system 100 as a distance measuring module, for example, a distance to a predetermined object as a subject can be measured and output as distance measurement data. Furthermore, in the viewing mode, viewing data can also be output.

<14. Application Example to Mobile Body>

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a boat, a robot, and the like.

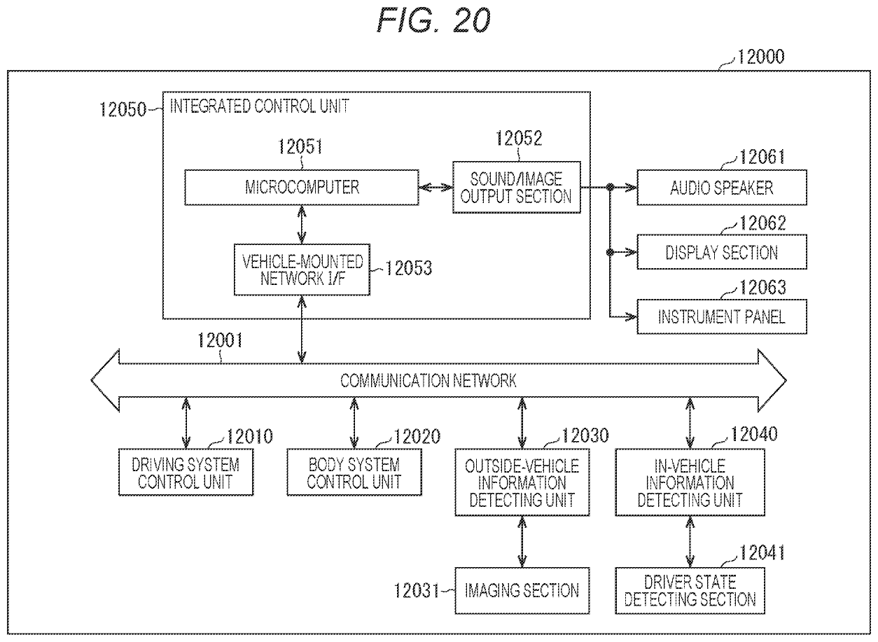

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are depicted as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of information regarding the outside of the vehicle, the information being acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are depicted as the output device. The display section 12062 may, for example, include at least one of an on-board display and a head-up display.

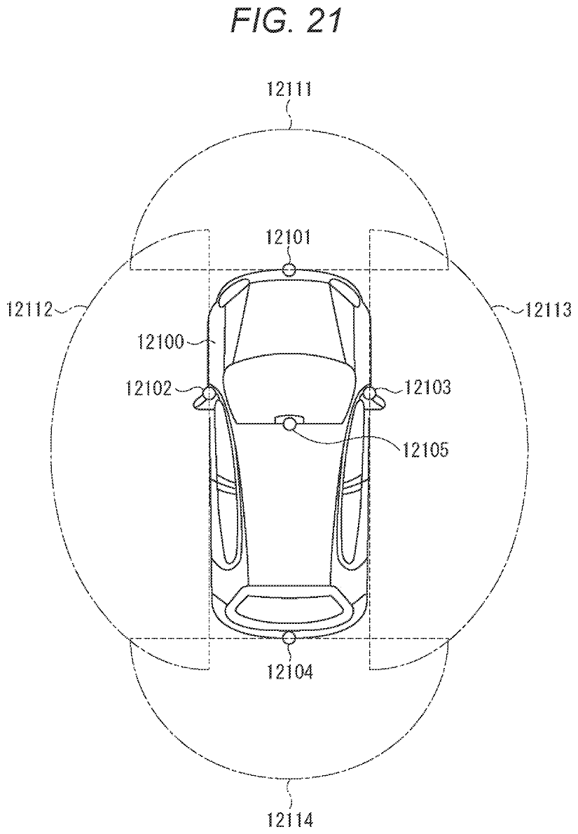

FIG. 21 is a diagram depicting an example of the installation position of the imaging section 12031.

In FIG. 21, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front obtained by the imaging sections 12101 and 12105 are used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure can be applied to the imaging section 12031 among the configurations described above. Specifically, the distance measuring system 100 in FIG. 16 can be applied as the imaging section 12031. By applying the technology according to the present disclosure to the imaging section 12031, distance information by the ToF method can be obtained. Furthermore, it is possible to reduce driver's fatigue and increase the safety of the driver and the vehicle by using the obtained captured image and distance information.

The embodiments of the present technology are not limited to the above-described embodiments, and various modifications are possible without departing from the gist of the present technology.

The plurality of present technologies which has been described in the present description can be each implemented independently as a single unit as long as no contradiction occurs. Of course, any plurality of the present technologies can also be used and implemented in combination. For example, part or all of the present technologies described in any of the embodiments can be implemented in combination with part or all of the present technologies described in other embodiments. Furthermore, part or all of any of the above-described present technologies can be implemented by using together with another technology that is not described above.

Further, for example, a configuration described as one device (or processing section) may be divided and configured as a plurality of devices (or processing sections). Conversely, configurations described above as a plurality of devices (or processing units) may be combined and configured as one device (or processing unit). In addition, a configuration other than those described above may be added to the configuration of each device (or each processing unit). Moreover, if the configuration and operation of the entire system are substantially the same, a part of the configuration of a certain device (or processing unit) may be included in the configuration of another device (or another processing unit).

Moreover, in the present description, a system means a set of a plurality of components (devices, modules (parts), and the like), and it does not matter whether or not all components are in the same housing. Therefore, both of a plurality of devices housed in separate housings and connected via a network and a single device in which a plurality of modules is housed in one housing are systems.

The embodiments of the present technology are not limited to the above-described embodiments, and various modifications are possible without departing from the gist of the present technology.

Note that the effects described in the present description are merely examples and are not limited, and effects other than those described in the present description may be provided.

Note that the present technology can have the following configurations.

(1)

A light receiving element, including:
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.

(2)

The light receiving element according to (1) above, in which
the third semiconductor region is arranged to surround an outer periphery of the first semiconductor region near the first surface of the substrate.

(3)

The light receiving element according to (2) above, in which
the third semiconductor region has a rectangular shape with a predetermined width surrounding an outer periphery of the first semiconductor region.

(4)

The light receiving element according to (2) or (3) above, in which
the third semiconductor region is arranged at a position at least partially overlapping the PN junction region in plan view.

(5)

The light receiving element according to any one of (1) to (4) above, in which
an impurity concentration of the third semiconductor region is same as an impurity concentration of the first semiconductor region.

(6)

The light receiving element according to any one of (1) to (5) above, in which
the pixel includes
a fourth semiconductor region of the second conductivity type arranged in an outer peripheral portion of a pixel region near the first surface of the substrate,
a first buried insulation film arranged between the first semiconductor region and the third semiconductor region, and
a second buried insulating film arranged between the third semiconductor region and the fourth semiconductor region.

(7)

The light receiving element according to (1) above, in which
the pixel includes
a fourth semiconductor region of the second conductivity type arranged at each corner of four corners of a rectangular pixel region near the first surface of the substrate.

(8)

The light receiving element according to (1) above, in which
the third semiconductor region is arranged in a plurality of regions outside the first semiconductor region near the first surface of the substrate.

(9)

The light receiving element according to (1) above, in which
the pixel includes
a fourth semiconductor region of the second conductivity type arranged at each corner of four corners of a rectangular pixel region near the first surface of the substrate,
a first buried insulation film arranged between the first semiconductor region and the third semiconductor region, and
a second buried insulating film arranged between the third semiconductor region and the fourth semiconductor region.

(10)

The light receiving element according to (1) above, in which
the third semiconductor region is arranged outside the PN junction region in plan view, and is formed from the first surface of the substrate to a position deeper than the PN junction region in cross-sectional view.

(11)

The light receiving element according to (1) above, in which
the third semiconductor region is arranged outside the PN junction region in plan view, and is formed from the first surface of the substrate to a substantially same position as the PN junction region in cross-sectional view.

(12)

The light receiving element according to (1) above, in which
the third semiconductor region includes
a first region arranged at a position at least partially overlapping with the PN junction region in plan view, and
a second region arranged outside the PN junction region in plan view and formed from the first surface of the substrate to at least a same position as the PN junction region in cross-sectional view.

(13)

The light receiving element according to any one of (1) to (12) above, in which
the pixel includes
a color filter and an on-chip lens on a second surface opposite to the first surface of the substrate.

(14)

A distance measuring system, including:
a light emitting section that emits irradiation light; and
a light receiving element that receives reflected light of the irradiation light reflected by a subject, in which
the light receiving element includes
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.

(15)

An electronic device, including:
a light receiving element that includes
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.

### REFERENCE SIGNS LIST

21 SPAD
10 Pixel
41 n-well
42 High-concentration n-type semiconductor region
43 High-concentration p-type semiconductor region
44, 44A, 44B High-concentration n-type semiconductor region
51 Inter-pixel isolation section
52 Insulating layer
53 Fixed charge film
54 Hole accumulation layer
55 High-concentration p-type semiconductor region
61, 62 Wiring
81, 82 Buried insulating film
91 Color filter
100 Distance measuring system
110 Control device
111 Distance measuring sensor
601 Smartphone
602 Distance measuring module

What is claimed is:

1. A light receiving element, comprising:
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.

2. The light receiving element according to claim 1, wherein
the third semiconductor region is arranged to surround an outer periphery of the first semiconductor region near the first surface of the substrate.

3. The light receiving element according to claim 2, wherein
the third semiconductor region has a rectangular shape with a predetermined width surrounding an outer periphery of the first semiconductor region.

4. The light receiving element according to claim 2, wherein
the third semiconductor region is arranged at a position at least partially overlapping the PN junction region in plan view.

5. The light receiving element according to claim 1, wherein
an impurity concentration of the third semiconductor region is same as an impurity concentration of the first semiconductor region.

6. The light receiving element according to claim 1, wherein
the pixel includes
a fourth semiconductor region of the second conductivity type arranged in an outer peripheral portion of a pixel region near the first surface of the substrate,
a first buried insulation film arranged between the first semiconductor region and the third semiconductor region, and
a second buried insulating film arranged between the third semiconductor region and the fourth semiconductor region.

7. The light receiving element according to claim 1, wherein
the pixel includes
a fourth semiconductor region of the second conductivity type arranged at each corner of four corners of a rectangular pixel region near the first surface of the substrate.

8. The light receiving element according to claim 1, wherein
the third semiconductor region is arranged in a plurality of regions outside the first semiconductor region near the first surface of the substrate.

9. The light receiving element according to claim 1, wherein
the pixel includes
a fourth semiconductor region of the second conductivity type arranged at each corner of four corners of a rectangular pixel region near the first surface of the substrate,
a first buried insulation film arranged between the first semiconductor region and the third semiconductor region, and
a second buried insulating film arranged between the third semiconductor region and the fourth semiconductor region.

10. The light receiving element according to claim 1, wherein
the third semiconductor region is arranged outside the PN junction region in plan view, and is formed from the first surface of the substrate to a position deeper than the PN junction region in cross-sectional view.

11. The light receiving element according to claim 1, wherein
the third semiconductor region is arranged outside the PN junction region in plan view, and is formed from the first surface of the substrate to a substantially same position as the PN junction region in cross-sectional view.

12. The light receiving element according to claim 1, wherein
the third semiconductor region includes
a first region arranged at a position at least partially overlapping with the PN junction region in plan view, and
a second region arranged outside the PN junction region in plan view and formed from the first surface of the substrate to at least a same position as the PN junction region in cross-sectional view.

13. The light receiving element according to claim 1, wherein
the pixel includes
a color filter and an on-chip lens on a second surface opposite to the first surface of the substrate.

14. A distance measuring system, comprising:
a light emitting section that emits irradiation light; and
a light receiving element that receives reflected light of the irradiation light reflected by a subject, wherein
the light receiving element includes
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.

15. An electronic device, comprising:
a light receiving element that includes
a pixel that includes
a PN junction region in which a first semiconductor region of a first conductivity type and a second semiconductor region of a second conductivity type opposite to the first conductivity type are joined, and
a third semiconductor region of the first conductivity type that is not connected to any wiring outside the first semiconductor region near a first surface of a substrate on which a wiring that supplies a predetermined power supply voltage to the first semiconductor region is formed.
